(19) United States
(12) Patent Application Publication
(10) Pub. No.: US 2024/0389450 A1
(43) Pub. Date: Nov. 21, 2024

(54) LIGHT EMITTING ELEMENT, PRODUCTION METHOD FOR LIGHT EMITTING ELEMENT, DISPLAY DEVICE, AND PRODUCTION METHOD FOR DISPLAY DEVICE

(71) Applicant: Sharp Display Technology Corporation, Kameyama City, Mie (JP)

(72) Inventor: Yang QU, Kameyama City, Mie (JP)

(21) Appl. No.: 18/691,544

(22) PCT Filed: Nov. 4, 2021
(86) PCT No.: PCT/JP2021/040567

§ 371 Date: Mar. 13, 2024

(51) Int. Cl. H10K 85/30; H10K 50/15; H10K 50/16; H10K 50/17

(52) U.S. Cl. CPC H10K 85/381; H10K 50/15; H10K 50/16; H10K 50/17; H10K 50/171

(57) ABSTRACT

Provided is a light-emitting element including: a first electrode; a first layer provided on the first electrode and including at least a light-emitting layer, the first layer being non-polar; an electron transport layer that is a second layer provided directly on the first layer and including at least one aromatic derivative selected from an aromatic derivative having a benzene ring skeleton containing one or more carboxyl groups and an aromatic derivative having a biphenyl skeleton containing one or more carboxyl groups, and metal oxide nanoparticles having electron transport properties; and a second electrode provided on the electron transport layer serving as the second layer.

### TECHNICAL FIELD

The disclosure relates to a light-emitting element, a manufacturing method of the light-emitting element, a display device, and a manufacturing method of the display device.

### BACKGROUND ART

In recent years, various display devices provided with a light-emitting element have been developed. In particular, display devices provided with an organic light-emitting diode (OLED) or a quantum dot light-emitting diode (QLED) have drawn a great deal of attention because these devices offer advantages such as lower power consumption, a thinner design, and higher picture quality.

PTL 1 discloses a light-emitting element provided with a light-emitting layer formed from quantum dots, and an electron transport layer including ZnO nanoparticles and formed directly on the light-emitting layer.

### CITATION LIST

### Patent Literature

PTL 1: JP 2018-517247 T

### SUMMARY

### Technical Problem

In the case of quantum dots, organic ligands formed from an organic molecule having a certain length are provided on the surface of each quantum dot in order to prevent aggregation of the quantum dots. Therefore, the surface of the light-emitting layer constituted by the quantum dots having the organic ligands exhibits non-polarity (water repellency). Meanwhile, a polar solvent must be used to disperse metal oxide nanoparticles (for example, ZnO nanoparticles) that exhibit polarity. Therefore, when a metal oxide nanoparticle solution constituted by a polar solvent and metal oxide nanoparticles exhibiting polarity is formed directly on the surface of a non-polar underlayer such as a non-polar (water repellent) light-emitting layer for example, the metal oxide nanoparticle solution is repelled, and thus coating characteristics are extremely poor and coating unevenness occurs. This results in an issue of extremely poor film formability of the metal oxide nanoparticles.

An aspect of the disclosure was developed in view of the above issue, and an object thereof is to provide a light-emitting element with improved film formability of metal oxide nanoparticles formed directly on a non-polar underlayer that includes at least a light-emitting layer, and to provide a display device, a manufacturing method of the light-emitting element, and a manufacturing method of the display device.

### Solution to Problem

In order to solve the issue described above, a light-emitting element of the disclosure includes:

a first electrode;

a first layer provided on the first electrode and including at least a light-emitting layer, the first layer being non-polar;

a second layer provided directly on the first layer and including at least one aromatic derivative selected from an aromatic derivative having a benzene ring skeleton containing one or more carboxyl groups and an aromatic derivative having a biphenyl skeleton containing one or more carboxyl groups, and metal oxide nanoparticles having electron transport properties or hole transport properties; and

a second electrode provided on the second layer.

In order to solve the issue described above, a display device of the disclosure includes:

a plurality of the above-described light-emitting elements provided on a substrate,

the plurality of the light-emitting elements including a first light-emitting element, a second light-emitting element, and a third light-emitting element,

wherein the first light-emitting element includes, as the light-emitting layer, a first light-emitting layer,

the second light-emitting element includes, as the light-emitting layer, a second light-emitting layer having a light-emission peak wavelength differing from a light-emission peak wavelength of the first light-emitting layer, and

the third light-emitting element includes, as the light-emitting layer, a third light-emitting layer having a light-emission peak wavelength differing from the light-emission peak wavelengths of the first light-emitting layer and the second light-emitting layer.

In order to solve the issue described above, a method of manufacturing a light-emitting element according to the disclosure includes:

forming a first electrode;

forming, on the first electrode, a first layer including at least a light-emitting layer, the first layer being non-polar;

forming a second layer by forming a mixed solution directly on the first layer, the mixed solution including at least one aromatic derivative selected from an aromatic derivative having a benzene ring skeleton containing one or more carboxyl groups and an aromatic derivative having a biphenyl skeleton containing one or more carboxyl groups, metal oxide nanoparticles having electron transport properties or hole transport properties, and a polar solvent; and

forming a second electrode on the second layer.

In order to solve the issue described above, a method of manufacturing a display device according to the disclosure includes:

forming a light-emitting element on a substrate by the method of manufacturing a light-emitting element described above.

### Advantageous Effects of Disclosure

An object of an aspect of the disclosure is to provide a light-emitting element with improved film formability of metal oxide nanoparticles formed directly on a non-polar underlayer that includes at least a light-emitting layer, and to provide a display device, a method of manufacturing the light-emitting element, and a method of manufacturing the display device.

### BRIEF DESCRIPTION OF DRAWINGS

FIG. 1 is a plan view illustrating a schematic configuration of a display device according to a first embodiment.

FIG. 2 is a cross-sectional view illustrating a schematic configuration of a display region of the display device according to the first embodiment.

FIG. 3 is a diagram illustrating a process for manufacturing the display device of the first embodiment, the manufacturing process including steps for manufacturing a red light-emitting element, a green light-emitting element, and a blue light-emitting element.

FIG. 4(a) is a cross-sectional view illustrating a schematic configuration of a red light-emitting element provided in the display device according to the first embodiment, FIG. 4(b) is a cross-sectional view illustrating a schematic configuration of a green light-emitting element provided in the display device according to the first embodiment, and FIG. 4(c) is a cross-sectional view illustrating a schematic configuration of a blue light-emitting element provided in the display device according to the first embodiment.

FIG. 5 is a diagram illustrating a process for forming each function layer in the process illustrated in FIG. 3 for manufacturing the display device of the first embodiment.

FIGS. 6(a), 6(b), 6(c) and 6(d) are diagrams illustrating steps for forming an electron transport layer provided in the display device of the first embodiment.

FIG. 7 is a graph showing a measurement result of a fluorescence lifetime of a green light-emitting element provided in the display device of the first embodiment and a measurement result of a fluorescence lifetime of a green light-emitting element of Comparative Example 1.

FIG. 8 is a graph showing a measurement result of a photoluminescence emission intensity (PL intensity) of the green light-emitting element provided in the display device of the first embodiment, a measurement result of the PL intensity of a green light-emitting element of Comparative Example 1, and a measurement result of a PL intensity of a green light-emitting element of Comparative Example 2.

FIG. 9 is a graph showing the current densities and voltage characteristics of the green light-emitting element provided in the display device of the first embodiment, of first to third modified examples of the green light-emitting element provided in the display device of the first embodiment, and of the green light-emitting element of Comparative Example 1.

FIG. 10 is a graph showing the current densities and luminance characteristics of the green light-emitting element provided in the display device of the first embodiment, of the first to third modified examples of the green light-emitting element provided in the display device of the first embodiment, and of the green light-emitting element of Comparative Example 1.

FIG. 11(a) is a graph showing the current densities and external quantum efficiency (EQE) characteristics of the green light-emitting element provided in the display device of the first embodiment, of the first to third modified examples of the green light-emitting element included in the display device of the first embodiment, and of the green light-emitting element of Comparative Example 1, and FIG. 11(b) is a partial enlarged view of a current density range of from 0 to 10 mA/cm² of the graph shown in FIG. 11(a) and showing the current densities and EQE characteristics.

FIG. 12 is a cross-sectional view illustrating a schematic configuration of a red light-emitting element provided in a display device of a second embodiment.

FIG. 13 is a cross-sectional view illustrating a schematic configuration of a red light-emitting element provided in a display device of a third embodiment.

FIGS. 14(a), 14(b), 14(c) and 14(d) are diagrams illustrating steps for forming a hole injection layer provided in the display device of the third embodiment.

FIG. 15 is a cross-sectional view illustrating a schematic configuration of a red light-emitting element provided in a display device of a fourth embodiment.

### DESCRIPTION OF EMBODIMENTS

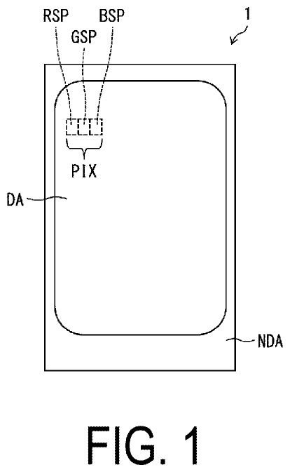

Embodiments of the disclosure will be described below with reference to FIGS. 1 to 15. Hereinafter, for convenience of description, configurations having the same functions as those described in a specific embodiment are denoted by the same reference signs, and descriptions thereof will be omitted.

### First Embodiment

FIG. 1 is a schematic plan view illustrating a configuration of a display device 1 according to a first embodiment.

As illustrated in FIG. 1, the display device 1 includes a frame region NDA and a display region DA. A plurality of pixels PIX are provided in the display region DA of the display device 1, and each pixel PIX includes a red subpixel RSP, a green subpixel GSP, and a blue subpixel BSP. In the present embodiment, a case will be described as an example in which one pixel PIX includes the red subpixel RSP, the green subpixel GSP, and the blue subpixel BSP, but no such limitation is intended. For example, one pixel PIX may further include a subpixel of another color in addition to the red subpixel RSP, the green subpixel GSP, and the blue subpixel BSP.

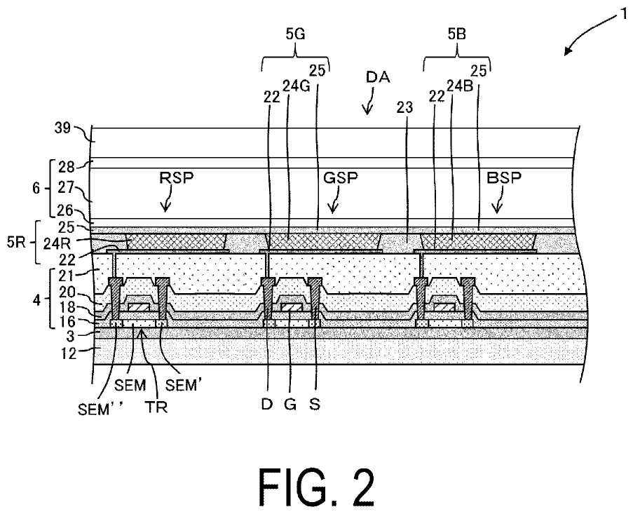

FIG. 2 is a cross-sectional view illustrating a schematic configuration of the display region DA of the display device 1 according to the first embodiment.

As illustrated in FIG. 2, in the display region DA of the display device 1, a barrier layer 3, a thin film transistor layer 4 including transistors TR, a red light-emitting element 5R, a green light-emitting element 5G, a blue light-emitting element 5B, and a bank 23, a sealing layer 6, and a function film 39 are provided on a substrate 12 in this order from the substrate 12 side.

The red subpixel RSP provided in the display region DA of the display device 1 includes a red light-emitting element 5R (first light-emitting element), the green subpixel GSP provided in the display region DA of the display device 1 includes a green light-emitting element 5G (second light-emitting element), and the blue subpixel BSP provided in the display region DA of the display device 1 includes a blue light-emitting element 5B (third light-emitting element).

The substrate 12 may be, for example, a resin substrate made of a resin material such as polyimide, or may be a glass substrate. In the present embodiment, the display device 1 is a flexible display device, and thus a case will be described as an example in which the resin substrate made of the resin material such as polyimide is used as the substrate 12. However, no such limitation is intended. In a case where the display device 1 is a non-flexible display device, the glass substrate may be used as the substrate 12.

The barrier layer 3 is a layer that inhibits foreign matter, such as water and oxygen, from entering the transistor TR, the red light-emitting element 5R, the green light-emitting element 5G, and the blue light-emitting element 5B, and can be formed of, for example, a silicon oxide film, a silicon nitride film, or a silicon oxynitride film, or a layered film thereof formed by chemical vapor deposition (CVD).

The transistor TR portion of the thin film transistor layer 4 including the transistor TR includes a semiconductor film SEM, doped semiconductor films SEM′ and SEM″, an inorganic insulating film 16, a gate electrode G, an inorganic insulating film 18, an inorganic insulating film 20, a source electrode S, a drain electrode D, and a flattening film 21. A portion other than the transistor TR portion of the thin film transistor layer 4 including the transistor TR includes the inorganic insulating film 16, the inorganic insulating film 18, the inorganic insulating film 20, and the flattening film 21.

The semiconductor films SEM, SEM′ and SEM″ may be formed of low-temperature polysilicon (LTPS) or an oxide semiconductor (for example, an In—Ga—Zn—O based semiconductor), for example. In the example of the present embodiment described herein, the transistor TR has a top gate structure. However, no such limitation is intended, and the transistor TR may have a bottom gate structure.

The gate electrode G, the source electrode S, and the drain electrode D may be formed of a single-layer film or a layered film of a metal including, for example, at least one of aluminum, tungsten, molybdenum, tantalum, chromium, titanium, or copper.

The inorganic insulating film 16, the inorganic insulating film 18, and the inorganic insulating film 20 may be formed of a silicon oxide film, a silicon nitride film, or a silicon oxynitride film, or a layered film thereof, formed by CVD.

The flattening film 21 may be formed of coatable organic materials such as polyimide and acrylic.

The red light-emitting element 5R included in the red subpixel RSP includes an anode, which is a first electrode 22 that is an upper layer overlying the flattening film 21, a function layer 24R including a red light-emitting layer, and a cathode, which is a second electrode 25. The green light-emitting element 5G included in the green subpixel GSP includes an anode, which is the first electrode 22 that is an upper layer overlying the flattening film 21, a function layer 24G including the green light-emitting layer, and a cathode, which is the second electrode 25. The blue light-emitting element 5B included in the blue subpixel BSP includes an anode, which is the first electrode 22 that is an upper layer overlying the flattening film 21, a function layer 24B including the blue light-emitting layer, and a cathode, which is the second electrode 25. Note that an insulating bank 23 covering the edge of the anode serving as the first electrode 22 can be formed, for example, by applying an organic material, such as a polyimide or acrylic, and then patterning the organic material by photolithography.

The function layer 24R including the red light-emitting layer may be formed by layering, for example, the hole injection layer, the hole transport layer, the red light-emitting layer, the electron transport layer, and the electron injection layer in this order from the anode side, which is the first electrode 22 side. Of the function layer 24R that includes the red light-emitting layer, one or more layers selected from the hole injection layer, the hole transport layer, and the electron injection layer may be omitted as appropriate. In the present embodiment, a case is described as an example in which the function layer 24R including the red light-emitting layer is formed by layering the hole injection layer, the hole transport layer, the red light-emitting layer, and the electron transport layer in this order from the anode side, the anode being the first electrode 22. However, the disclosure is not limited thereto.

The function layer 24G including the green light-emitting layer may be formed by layering, for example, a hole injection layer, a hole transport layer, the green light-emitting layer, an electron transport layer, and an electron injection layer in this order from the anode side, the anode being the first electrode 22. Of the function layer 24G that includes the green light-emitting layer, one or more layers selected from the hole injection layer, the hole transport layer, and the electron injection layer may be omitted as appropriate. In the present embodiment, a case is described as an example in which the function layer 24G including the green light-emitting layer is formed by layering the hole injection layer, the hole transport layer, the green light-emitting layer, and the electron transport layer in this order from the anode side, the anode being the first electrode 22. However, the disclosure is not limited thereto.

The function layer 24B including the blue light-emitting layer may be formed by layering, for example, the hole injection layer, the hole transport layer, the blue light-emitting layer, the electron transport layer, and the electron injection layer in this order from the anode side, the anode being the first electrode 22. Of the function layer 24B that includes the blue light-emitting layer, one or more layers selected from the hole injection layer, the hole transport layer, and the electron injection layer may be omitted as appropriate. In the present embodiment, a case is described as an example in which the function layer 24B including the blue light-emitting layer is formed by layering the hole injection layer, the hole transport layer, the blue light-emitting layer, and the electron transport layer in this order from the anode side, the anode being the first electrode 22. However, the disclosure is not limited thereto.

In the present embodiment, a case is described as an example in which the function layer 24R including the red light-emitting layer, the function layer 24G including the green light-emitting layer, and the function layer 24B including the blue light-emitting layer each includes the hole injection layer formed using the same material in the same process, the hole transport layer formed using the same material in the same process, and the electron transport layer formed using the same material in the same process. However, the disclosure is not limited thereto. For example, the hole injection layers included respectively in the function layers 24R, 24G, and 24B may be formed of materials different from each other. For example, the hole injection layers each included in a respective one of two function layers of the function layers 24R, 24G, and 24B may be formed of the same material in the same process, and only the hole injection layer included in the remaining one function layer may be formed of a different material in another process. In addition, for example, the hole transport layers included respectively in the function layers 24R, 24G, and 24B may be formed of materials different from each other. For example, the hole transport layers included respectively in two function layers of the function layers 24R, 24G, and 24B may be formed of the same material in the same process, and only the hole transport layer included in the remaining one function layer may be formed of a different material in another process. Furthermore, for example, the electron transport layers included respectively in the function layers 24R, 24G, and 24B may be formed of materials different from each other. For example, the electron transport layers included respectively in two function layers of the function layers 24R, 24G, and 24B may be formed of the same material in the same process, and only the electron transport layer included in the remaining one function layer may be formed of a different material in another process.

In the present embodiment, a case will be described as an example where the red light-emitting element 5R, the green light-emitting element 5G, and the blue light-emitting element 5B are QLEDs (quantum dot light-emitting diodes), but no such limitation is intended. The red light-emitting element 5R, the green light-emitting element 5G, and the blue light-emitting element 5B may be OLEDs (organic light-emitting diodes), or one or some elements of the red light-emitting element 5R, the green light-emitting element 5G, and the blue light-emitting element 5B may be QLEDs, and the remaining element or elements of the red light-emitting element 5R, the green light-emitting element 5G, and the blue light-emitting element 5B may be OLEDs.

When the red light-emitting element 5R, the green light-emitting element 5G, and the blue light-emitting element 5B are QLEDs, the light-emitting layers included in the light-emitting elements of the respective colors are formed of quantum dots (QDs). The surface of each quantum dot (QD) is provided with an organic ligand constituted by an organic molecule having a certain length in order to prevent aggregation of the quantum dots (QDs). Therefore, the surface of the light-emitting layer constituted by the quantum dots having the organic ligands exhibits non-polarity (water repellency). The quantum dots (QDs) may have, for example, a core structure, a core/shell structure, a core/shell/shell structure, or a core/shell with continuously varying ratio structure. When the quantum dot (QD) has a core structure, the organic ligands are provided on the surface of the core, and when the quantum dot (QD) has a shell structure, the organic ligands are provided on the surface of the shell. The core may be composed of, for example, Si, C, or the like in a case of a unary system, composed of, for example, CdSe, CdS, CdTe, InP, GaP, InN, ZnSe, ZnS, ZnTe, or the like in a case of a binary system, composed of, for example, CdSeTe, GaInP, ZnSeTe, or the like in a case of a ternary system, and composed of, for example, AIGS or the like in a case of a quaternary system. The shell can be composed of, for example, CdS, CdTe, CdSe, ZnS, ZnSe, ZnTe, or the like in a case of a binary system, and composed of, for example, CdSSe, CdTeSe, CdSTe, ZnSSe, ZnSTe, ZnTeSe, AlP, or the like in a case of a ternary system.

Note that a quantum dot is a dot having a maximum width of 100 nm or less. The shape of the quantum dot is not particularly limited as long as it is within a range satisfying the maximum width, and the shape is not limited to a spherical three-dimensional shape (circular cross-sectional shape). The shape of the quantum dot may be, for example, a polygonal cross-sectional shape, a rod-shaped three-dimensional shape, a branch-shaped three-dimensional shape, or a three-dimensional shape having unevenness on the surface thereof, or a combination thereof.

When each of the red light-emitting element 5R, the green light-emitting element 5G, and the blue light-emitting element 5B is an OLED, the light-emitting layer included in the light-emitting element of each color is, for example, an organic light-emitting layer formed by a vapor deposition method. Since the organic light-emitting layer is constituted by organic molecules, the surface of the organic light-emitting layer exhibits non-polarity (water repellency).

A control circuit including the transistors TR each of which controls a respective one of the red light-emitting element 5R, the green light-emitting element 5G, and the blue light-emitting element 5B is provided in the thin film transistor layer 4 including the transistors TR corresponding to the red subpixel RSP, the green subpixel GSP, and the blue subpixel BSP. Note that the control circuit including the transistors TR provided corresponding to the red subpixel RSP, the green subpixel GSP, and the blue subpixel BSP and the light-emitting elements are collectively referred to as a subpixel circuit.

The red light-emitting element 5R, the green light-emitting element 5G, and the blue light-emitting element 5B illustrated in FIG. 2 may be a top-emitting type or a bottom-emitting type. The red light-emitting element 5R, the green light-emitting element 5G, and the blue light-emitting element 5B each have an ordered-layered structure in which the anode serving as the first electrode 22, the function layer 24R, 24G, or 24B, and the cathode serving as the second electrode 25 are formed in this order from the substrate 12 side, and thus the cathode serving as the second electrode 25 is disposed as an upper layer above the anode serving as the first electrode 22. Therefore, to realize a top-emitting type light-emitting element, the anode serving as the first electrode 22 may be formed of an electrode material that reflects visible light, and the cathode serving as the second electrode 25 may be formed of an electrode material that allows the transmission of visible light. Furthermore, to realize a bottom-emitting type light-emitting element, the anode serving as the first electrode 22 may be formed of an electrode material that allows the transmission of visible light, and the cathode serving as the second electrode 25 may be formed of an electrode material that reflects visible light.

The electrode material that reflects visible light is not particularly limited as long as the material can reflect visible light and has electrical conductivity. Examples include metal materials such as Al, Mg, Li, and Ag, alloys of the metal materials, a layered body of the metal materials and transparent metal oxides (for example, indium tin oxide, indium zinc oxide, indium gallium zinc oxide, and the like), or a layered body of the alloys and the transparent metal oxides.

On the other hand, the electrode material that transmits visible light is not particularly limited as long as the material can transmit visible light and has electrical conductivity. Examples include a thin film formed of a transparent metal oxide (for example, indium tin oxide, indium zinc oxide, indium gallium zinc oxide, and the like) or a metal material such as Al and Ag, or a nano wire formed of a metal material such as Al and Ag.

In the present embodiment, a case is described as an example in which the red light-emitting element 5R, the green light-emitting element 5G, and the blue light-emitting element 5B are top-emitting types, each of the anodes serving as a first electrode 22 is formed of a layered film of ITO/Ag/ITO, which is an electrode material that reflects visible light, and each of the cathodes serving as a second electrode 25 is formed of a nanowire formed from Ag, which is an electrode material that transmits visible light. However, the disclosure is not limited thereto.

A typical electrode forming method may be used as a film formation method of the anode serving as the first electrode 22 and the cathode serving as the second electrode 25, and examples thereof include physical vapor deposition (PVD) methods such as vacuum vapor deposition, sputtering, electron beam (EB) vapor deposition, and ion plating, or a chemical vapor deposition (CVD) method. Further, the method of patterning the anode serving as the first electrode 22 and the cathode serving as the second electrode 25 is not particularly limited as long as the method can be used to precisely form a desired pattern, and specific examples include a photolithography method and an ink-jet method.

The sealing layer 6 is a transparent film and, for example, may be formed of an inorganic sealing film 26 for covering the cathode serving as the second electrode 25, an organic film 27 that is an upper layer overlying the inorganic sealing film 26, and an inorganic sealing film 28 that is an upper layer overlying the organic film 27. The sealing layer 6 inhibits foreign matters such as water and oxygen from penetrating into the red light-emitting element 5R, the green light-emitting element 5G, and the blue light-emitting element 5B.

The inorganic sealing film 26 and the inorganic sealing film 28 are both inorganic films and may be formed of, for example, a silicon oxide film, a silicon nitride film, a silicon oxynitride film, or a layered film thereof, formed by CVD. The organic film 27 is a transparent organic film having a flattening effect, and may be formed of a coatable organic material such as acrylic, for example. The organic film 27 may be formed by an ink-jet method, for example. The case has been described as an example of the present embodiment in which the sealing layer 6 is formed of two layers of an inorganic film and one layer of an organic film provided between the two layers of the inorganic film. However, the layering order of the two layers of the inorganic film and the one layer of the organic film is not limited thereto. Further, the sealing layer 6 may be formed of only an inorganic film, may be formed of only an organic film, may be formed of one layer of an inorganic film and two layers of an organic film, or may be formed of two or more layers of an inorganic film and two or more layers of an organic film.

The function film 39 is a film with at least one of an optical compensation function, a touch sensor function, or a protection function, for example.

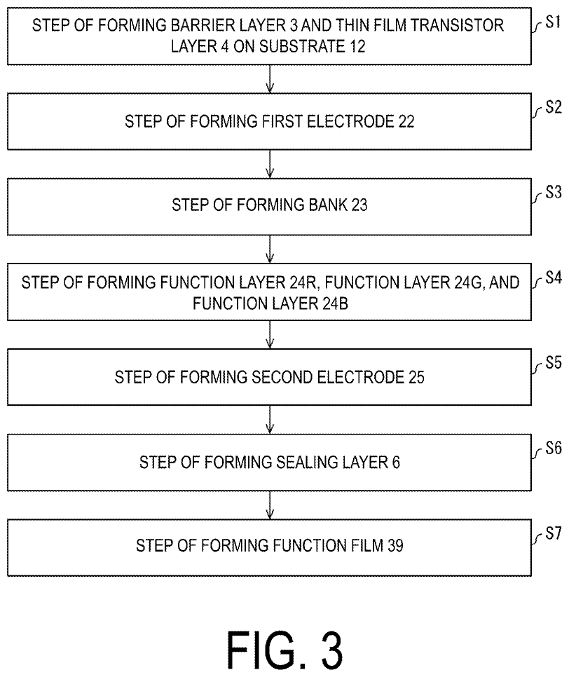

FIG. 3 is a diagram describing a process for manufacturing the display device 1 of the first embodiment, the manufacturing process including steps for manufacturing the red light-emitting element 5R, the green light-emitting element 5G, and the blue light-emitting element 5B.

As illustrated in FIG. 3, the manufacturing process for the display device 1 illustrated in FIG. 2 includes a step (S1) of forming the barrier layer 3 and the thin film transistor layer 4 on the substrate 12, a step (S2) of forming the first electrode 22, a step (S3) of forming the bank 23, a step (S4) of forming the function layer 24R including the red light-emitting layer included in the red light-emitting element 5R, the function layer 24G including the green light-emitting layer included in the green light-emitting element 5G, and the function layer 24B including the blue light-emitting layer included in the blue light-emitting element 5B, a step (S5) of forming the second electrode 25, a step (S6) of forming the sealing layer 6, and a step (S7) of forming the function film 39.

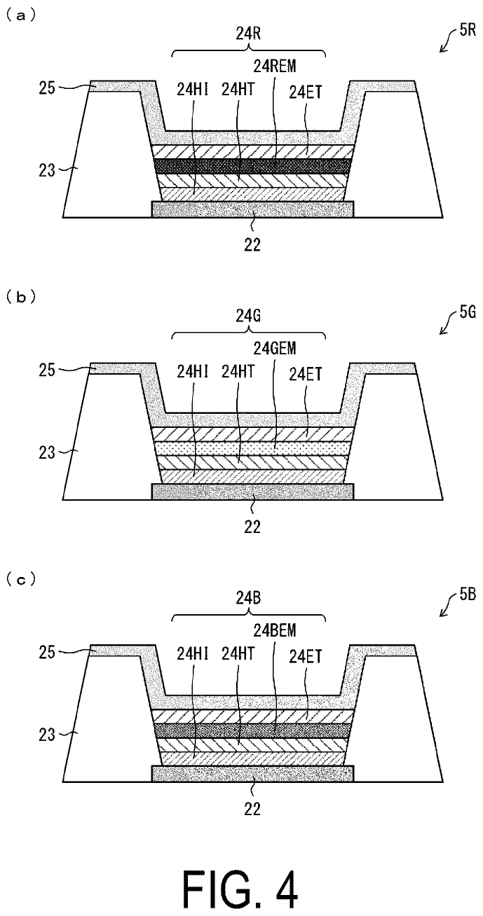

(a) of FIG. 4 is a cross-sectional view illustrating a schematic configuration of the red light-emitting element 5R provided in the display device 1 according to the first embodiment, (b) of FIG. 4 is a cross-sectional view illustrating a schematic configuration of the green light-emitting element 5G provided in the display device 1 according to the first embodiment, and (c) of FIG. 4 is a cross-sectional view illustrating a schematic configuration of the blue light-emitting element 5B provided in the display device 1 according to the first embodiment.

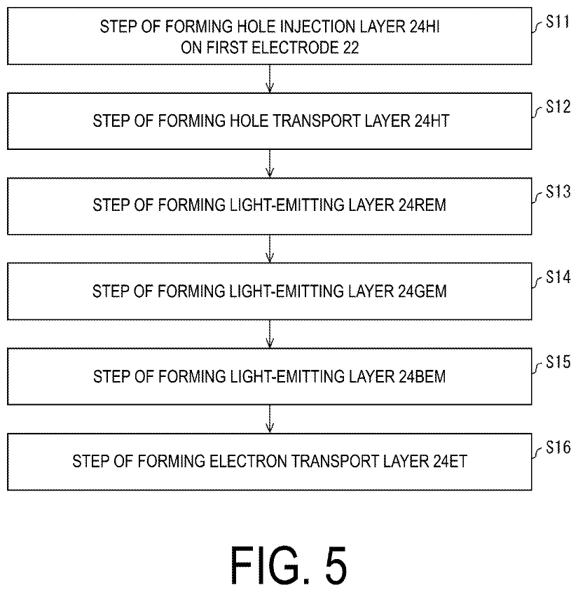

FIG. 5 is a diagram describing the process for forming the function layer 24R, the function layer 24G, and the function layer 24B in the process for manufacturing the display device 1 of the first embodiment illustrated in FIG. 3.

As illustrated in FIG. 5, the process of forming the function layers 24R, 24G, and 24B provided in the display device 1 includes a step (S11) of forming a hole injection layer 24HI on the anode serving as the first electrode 22, a step (S12) of forming a hole transport layer 24HT, a step (S13) of forming a light-emitting layer 24REM (red light-emitting layer), a step (S14) of forming a light-emitting layer 24GEM (green light-emitting layer), a step (S15) of forming a light-emitting layer 24BEM (blue light-emitting layer), and a step (S16) of forming an electron transport layer 24ET.

In the present embodiment, a case is described as an example in which the light-emitting layer 24REM (red light-emitting layer), the light-emitting layer 24GEM (green light-emitting layer), and the light-emitting layer 24BEM (blue light-emitting layer) are formed in this order. However, no such limitation is intended, and the light-emitting layers may be formed in any order.

Also, in the present embodiment, as described above, the function layer 24R, the function layer 24G, and the function layer 24B are each provided with the hole injection layer 24HI formed using the same material in the same process, the hole transport layer 24HT formed using the same material in the same process, and the electron transport layer 24ET formed using the same material in the same process. Therefore, in the step (S11) of forming the hole injection layer 24HI on the anode serving as the first electrode 22, as illustrated in (a) of FIG. 4, (b) of FIG. 4, and (c) of FIG. 4, the hole injection layer 24HI is formed on the anode that serves as the first electrode 22 provided in each of the red light-emitting element 5R, the green light-emitting element 5G, and the blue light-emitting element 5B. In the step (S12) of forming the hole transport layer 24HT, as illustrated in (a) of FIG. 4, (b) of FIG. 4, and (c) of FIG. 4, the hole transport layer 24HT is formed on the hole injection layer 24HI provided in each of the red light-emitting element 5R, the green light-emitting element 5G, and the blue light-emitting element 5B. Further, in the step (S16) of forming the electron transport layer 24ET, as illustrated in (a) of FIG. 4, (b) of FIG. 4, and (c) of FIG. 4, the electron transport layer 24ET is formed on the light-emitting layer 24REM (red light-emitting layer) provided in the red light-emitting element 5R, on the light-emitting layer 24GEM (green light-emitting layer) provided in the green light-emitting element 5G, and on the light-emitting layer 24BEM (blue light-emitting layer) provided in the blue light-emitting element 5B.

The anode serving as the first electrode 22 can be formed with a film thickness of, for example, from 100 nm to 300 nm, but is not limited thereto. The cathode serving as the second electrode 25 can be formed with a film thickness of, for example, from 10 nm to 100 nm, but is not limited thereto. The hole injection layer 24HI can be formed with a film thickness of, for example, from 20 nm to 90 nm, but is not limited thereto. The hole transport layer 24HT can be formed with a film thickness of, for example, from 20 nm to 70 nm, but is not limited thereto. The light-emitting layer 24REM (red light-emitting layer), the light-emitting layer 24GEM (green light-emitting layer), and the light-emitting layer 24BEM (blue light-emitting layer) can each be formed with a film thickness of, for example, from 20 nm to 50 nm, but are not limited thereto. The electron transport layer 24ET can be formed with a film thickness of, for example, from 30 nm to 90 nm, but is not limited thereto.

In the present embodiment, the light-emitting layer 24REM (red light-emitting layer), the light-emitting layer 24GEM (green light-emitting layer), and the light-emitting layer 24BEM (blue light-emitting layer) are formed of quantum dots (QDs), and the surface of each quantum dot (QD) is provided with organic ligands formed of organic molecules having a certain length in order to prevent aggregation of the quantum dots (QDs). Therefore, the surface of each light-emitting layer constituted by quantum dots provided with organic ligands exhibits non-polarity (water repellency).

When an electron transport layer containing metal oxide nanoparticles having electron transport properties is formed directly on each of the light-emitting layer 24REM (red light-emitting layer), the light-emitting layer 24GEM (green light-emitting layer), and the light-emitting layer 24BEM (blue light-emitting layer), which are provided on the respective first electrodes 22 and are non-polar underlayers (first layers) including at least the light-emitting layer, the following issues occur.

A polar solvent is generally used to disperse the metal oxide nanoparticles (ZnO nanoparticles, for example) that exhibit polarity, and therefore when a metal oxide nanoparticle solution constituted by a polar solvent and metal oxide nanoparticles exhibiting polarity is formed directly on the surfaces of the light-emitting layers 24REM (red light-emitting layer), 24GEM (green light-emitting layer), and 24BEM (blue light-emitting layer), which are non-polar (water-repellent) underlayers, the metal oxide nanoparticle solution is repelled, resulting in extremely poor coating characteristics and coating unevenness, and therefore an issue of extremely poor film formability of the metal oxide nanoparticles exists. Note that directly on a certain layer or directly on a surface of a certain layer means in contact with the certain layer or in contact with the surface of the certain layer.

In the present embodiment, at least one aromatic derivative selected from among an aromatic derivative having a benzene ring skeleton containing one or more carboxyl groups and an aromatic derivative having a biphenyl skeleton containing one or more carboxyl groups is added to the electron transport layer 24ET in order to improve the film formability of the electron transport layer 24ET (second layer), that is, the metal oxide nanoparticles having electron transport properties, with the electron transport layer 24ET (second layer) including metal oxide nanoparticles having electron transport properties and formed directly on each of the light-emitting layer 24REM (red light-emitting layer), the light-emitting layer 24GEM (green light-emitting layer), and the light-emitting layer 24BEM (blue light-emitting layer), which are non-polar underlayers. Note that the reason why at least one aromatic derivative selected from among an aromatic derivative having a benzene ring skeleton and an aromatic derivative having a biphenyl skeleton is used is that an aromatic derivative in which three or more benzene rings are connected, for example, an aromatic derivative having a terphenyl skeleton, causes of issue of solubility.

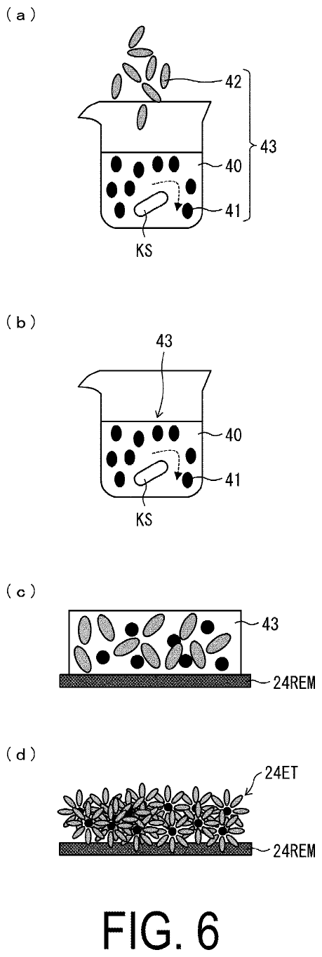

(a) of FIG. 6, (b) of FIG. 6, (c) of FIG. 6, and (d) of FIG. 6 are diagrams illustrating steps for forming the electron transport layer 24ET included in the display device 1 according to the first embodiment.

In the present embodiment, as illustrated in (a) of FIG. 6, an aromatic derivative 42 described above is added while stirring, with a stirrer KS for example, a metal oxide nanoparticle dispersion obtained by dispersing metal oxide nanoparticles 41 having electron transport properties in a polar solvent 40, and further stirring with, for example, the stirrer KS to thereby manufacture, as illustrated in (b) of FIG. 6, an electron transport material mixed solution 43 containing the polar solvent 40, the metal oxide nanoparticles 41 having electron transport properties, and the above-described aromatic derivative 42. The electron transport material mixed solution 43 is not limited to this, and may be manufactured by simultaneously inserting the metal oxide nanoparticles 41 having electron transport properties and the above-described aromatic derivative 42 into the polar solvent 40 and stirring the mixture using, for example, the stirrer KS.

Subsequently, as illustrated in (c) of FIG. 6, the electron transport material mixed solution 43 can be formed directly on the light-emitting layer 24REM (red light-emitting layer), the light-emitting layer 24GEM (green light-emitting layer), and the light-emitting layer 24BEM (blue light-emitting layer), which are non-polar underlayers, by using, for example, a spin coating method, an ink-jet method, a bar coating method, a blade coating method, a roll coating method, a dipping method, a gravure coating method, a flexographic printing method, or a spray coating method. Among these methods, by using the ink-jet method, the electron transport material mixed solution 43 can be formed only inside a frame-shaped bank 23 illustrated in (a) of FIG. 4, (b) of FIG. 4, and (c) of FIG. 4, and the electron transport layer 24ET can be selectively formed only in necessary locations without increasing the number of manufacturing steps.

Subsequently, as illustrated in (c) of FIG. 6, the polar solvent 40 is removed by heat treating (for example, at 80° C. for a predetermined amount of time), as necessary, the electron transport material mixed solution 43 formed directly on each of the light-emitting layer 24REM (red light-emitting layer), the light-emitting layer 24GEM (green light-emitting layer), and the light-emitting layer 24BEM (blue light-emitting layer), which are non-polar underlayers, and thereby, as illustrated in (d) of FIG. 6, the electron transport layer 24ET can be formed directly on the light-emitting layer 24REM (red light-emitting layer), the light-emitting layer 24GEM (green light-emitting layer), and the light-emitting layer 24BEM (blue light-emitting layer), which are non-polar underlayers. The heat treatment temperature and the heat treatment time can be appropriately set according to the type of the polar solvent 40 to be used. The heat treatment is preferably implemented to further improve productivity, but the disclosure is not limited thereto, and for example, the electron transport material mixed solution 43 formed on the light-emitting layers may be left standing at room temperature without being subjected to the heat treatment.

The surfaces of the metal oxide nanoparticles 41 having polarity and electron transport properties and contained in the electron transport layer 24ET illustrated in (d) of FIG. 6 are chemically modified with at least one aromatic derivative selected from an aromatic derivative having a benzene ring skeleton containing one or more carboxyl groups and an aromatic derivative having a biphenyl skeleton containing one or more carboxyl groups. Specifically, when the carboxyl group of the above-described aromatic derivative 42 is disposed on the surface of the metal oxide nanoparticle 41 having polarity and electron transport properties, the aromatic derivative having a benzene ring skeleton and/or the aromatic derivative having a biphenyl skeleton covers the surface of the metal oxide nanoparticle 41 having polarity and electron transport properties, and therefore the surface of the metal oxide nanoparticle 41 having electron transport properties is made non-polar (water repellent). Accordingly, the film formability of the metal oxide nanoparticles 41 having electron transport properties and formed directly on the light-emitting layer 24REM (red light-emitting layer), the light-emitting layer 24GEM (green light-emitting layer), and the light-emitting layer 24BEM (blue light-emitting layer), which are non-polar underlayers, can be improved.

As the metal oxide nanoparticles 41 having electron transport properties, nanoparticles of a metal oxide containing at least one selected from Zn, Mg, Ti, Si, Sn, W, Ta, Ba, Zr, Al, Y, and Hf are preferably used, and nanoparticles of zinc oxide (ZnO) or magnesium zinc oxide (MgZnO) are more preferably used. Note that the particle size of the metal oxide nanoparticle 41 is preferably from 2 nm to 30 nm. Setting the particle size of the metal oxide nanoparticle 41 to equal to or greater than 2 nm facilitates control of the particle size of the metal oxide nanoparticle 41. Furthermore, when the particle size of the metal oxide nanoparticle 41 is set to equal to or less than the 30 nm, the efficiency of injection of electrons from the cathode serving as the second electrode 25 into the electron transport layer 24ET can be improved.

As the polar solvent 40, it is preferable to use an alcohol-based solvent in consideration of the dispersibility of the metal oxide nanoparticles 41 exhibiting polarity and electron transport properties, and for example, ethanol, propanol, butanol, or the like can be suitably used.

As the aromatic derivative 42 described above, an aromatic derivative having a benzene ring skeleton containing one or more carboxyl groups as described in Chemical Formula 1 below can be used.

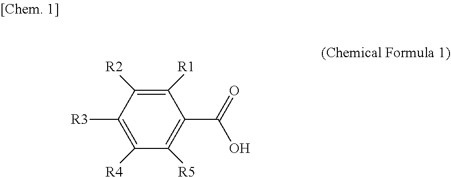

With regard to R1 to R5 in Chemical Formula 1 described above, for example, some may be alkyl groups having 5 or few carbons, and the remainder may be protons (cations of hydrogen atoms). Examples thereof include, but are not limited to, methylbenzoic acid, ethylbenzoic acid, propylbenzoic acid, butylbenzoic acid, pentylbenzoic acid, and dimethylbenzoic acid.

As in the present embodiment, when the surface of the metal oxide nanoparticle 41 exhibiting polarity and electron transport properties and contained in the electron transport layer 24ET is modified, one or more of R1 to R5 are preferably electron-donating groups, and more preferably, all of R1 to R5 are electron-donating groups. The electron-donating group is preferably any of an amino group, a methoxy group, an ethoxy group, or a proton. Through chemical modification using the aromatic derivative 42 including the electron-donating group in this manner, the metal oxide nanoparticles 41 having electron transport properties can be configured so as to have a dipolar property, and as described below, the light-emission characteristics and element characteristics of the red light-emitting element 5R, the green light-emitting element 5G, and the blue light-emitting element 5B can be improved.

The following Chemical Formula 2 is an amino-benzoic acid (for example, p-amino-benzoic acid) and is an example of an aromatic derivative having a benzene ring skeleton containing one or more carboxyl groups. In the compound of Chemical Formula 2, R3 of Chemical Formula 1 described above is an amino group, which is an electron-donating group, and R1, R2, R4, and R5 of Chemical Formula 1 are each a proton, which is an electron-donating group.

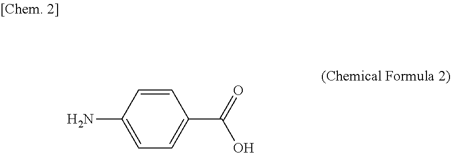

The following Chemical Formula 3 is a benzoic acid and is an example of an aromatic derivative having a benzene ring skeleton containing one or more carboxyl groups. In the compound of Chemical Formula 3, R1 to R5 of the above Chemical Formula 1 are each a proton serving as an electron-donating group.

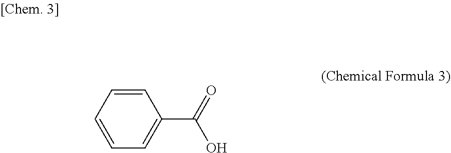

Although not illustrated, the aromatic derivative of the benzene ring skeleton having one or more carboxyl groups may be a methoxybenzoic acid (for example, 4-methoxybenzoic acid) including a methoxy group and a proton as electron-donating groups, or may be ethoxybenzoic acid (for example, p-ethoxybenzoic acid) including an ethoxy group and a proton as electron-donating groups.

In addition, the aromatic derivative 42 described above may be an aromatic derivative having a biphenyl skeleton with one or more carboxyl groups, as represented by Chemical Formula 4 below.

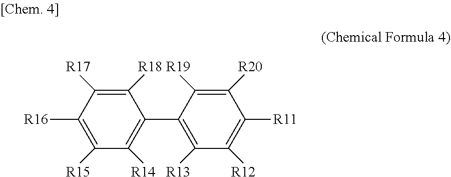

At least one of R11 to R20 in the above Chemical Formula 4 is a carboxyl group, and the remaining of R11 to R20 other than the carboxyl group in the above Chemical Formula 4 may be constituted by, for example, an alkyl group having 5 or fewer carbons and a proton. Examples thereof include, but are not limited to, methyl biphenylcarboxylic acids (for example, 4′-methyl-3-biphenylcarboxylic acid), ethyl biphenylcarboxylic acids (for example, 4-ethylbiphenyl-4′-carboxylic acid), propyl biphenylcarboxylic acids (for example, 4-(4-propylphenyl) benzoic acid), butyl biphenylcarboxylic acids (for example, 4-(4-N-butylphenyl) benzoic acid), and pentyl biphenylcarboxylic acids (for example, 4-pentyl-4′-biphenylcarboxylic acid).

When the surface of the metal oxide nanoparticle 41 exhibiting polarity and electron transport properties and contained in the electron transport layer 24ET is modified as in the present embodiment, one or more of the remaining of R11 to R20 other than the carboxyl group in Chemical Formula 4 are preferably electron donating groups, and more preferably, all of the remaining of R11 to R20 other than the carboxyl groups in Chemical Formula 4 are electron-donating groups. The electron-donating group is preferably any of an amino group, a methoxy group, an ethoxy group, or a proton. Through chemical modification using the aromatic derivative 42 including the electron-donating group in this manner, the metal oxide nanoparticles 41 having electron transport properties can be configured so as to have a dipolar property, and as described below, the light-emission characteristics and element characteristics of the red light-emitting element 5R, the green light-emitting element 5G, and the blue light-emitting element 5B can be improved.

The following Chemical Formula 5 is a biphenylcarboxylic acid and is an example of an aromatic derivative having a biphenyl skeleton containing one or more carboxyl groups. In the compound of Chemical Formula 5, R11 of the above Chemical Formula 4 is a carboxyl group and R12 to R20 of the above Chemical Formula 4 are protons, which are electron-donating groups.

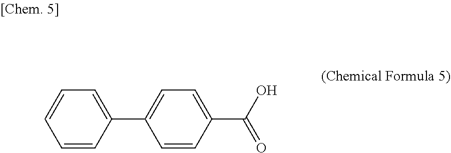 [SMILES: O=C(O)c1ccc(-c2ccccc2)cc1]

The following Chemical Formula 6 is an amino biphenylcarboxylic acid (for example, 4′-aminobiphenyl-4-carboxylic acid), and is an example of an aromatic derivative having a biphenyl skeleton containing one or more carboxyl groups. In the compound of Chemical Formula 6, R11 of Chemical Formula 4 described above is a carboxyl group, R16 of Chemical Formula 4 is amino group, which is an electron-donating group, and R12 to R15 and R17 to R20 of Chemical Formula 4 are protons, which are electron-donating groups.

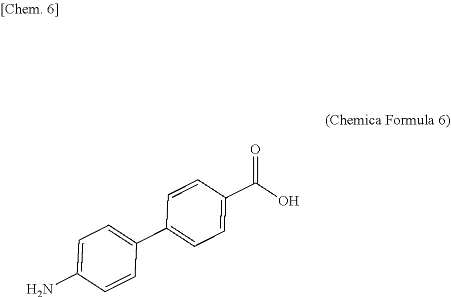 [SMILES: Nc1ccc(-c2ccc(C(=O)O)cc2)cc1]

The following Chemical Formula 7 is a methoxy biphenylcarboxylic acid (for example, 4′-methoxy-3-biphenylcarboxylic acid), and is an example of an aromatic derivative having a biphenyl skeleton containing one or more carboxyl groups. In the compound of Chemical Formula 7, R20 in Chemical Formula 4 described above is a carboxyl group, R16 in Chemical Formula 4 is a methoxy group, which is an electron-donating group, and R11 to R15 and R17 to R19 in Chemical Formula 4 are protons, which are electron-donating groups.

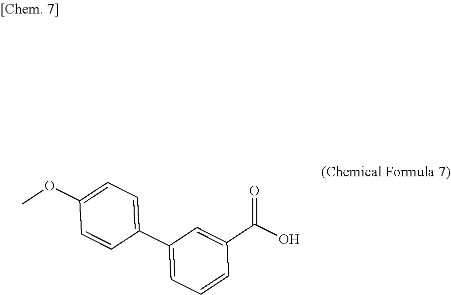 [SMILES: COc1ccc(-c2cccc(C(=O)O)c2)cc1]

Although not illustrated, the aromatic derivative of the biphenyl skeleton having one or more carboxyl groups may be an ethoxy biphenylcarboxylic acid (for example, 4-ethoxy-4′-biphenylcarboxylic acid) including an ethoxy group and a proton, which are electron-donating groups.

Further, as the aromatic derivative 42 described above, both the above-described aromatic derivative having a benzene ring skeleton containing one or more carboxyl groups and one or more electron-donating groups and the above-described aromatic derivative having a biphenyl skeleton containing one or more carboxyl groups and one or more electron-donating groups may be mixed and used.

From the viewpoint of improving the film formability of the metal oxide nanoparticles 41 having electron transport properties, nitro-benzoic acid represented by Chemical Formula 8, cyano-benzoic acid represented by Chemical Formula 9, bromo-biphenylcarboxylic acid represented by Chemical Formula 10, or the like, which will be described later in a third embodiment, may be used as the aromatic derivative 42 described above.

The aromatic derivative having a benzene ring skeleton containing one carboxyl group and the aromatic derivative having a biphenyl skeleton containing one carboxyl group were described above as examples. However, the disclosure is not limited thereto, and an aromatic derivative having a benzene ring skeleton containing a plurality of carboxyl groups and an aromatic derivative having a biphenyl skeleton containing a plurality of carboxyl groups may be used.

In the present embodiment, an example was described in which ethanol was used as the polar solvent 40, nanoparticles of zinc oxide (ZnO) were used as the metal oxide nanoparticles 41 having electron transport properties, and amino-benzoic acid represented by Chemical Formula 2 above was used as the aromatic derivative 42 described above. However, the disclosure is not limited thereto. Furthermore, the amount of amino-benzoic acid added to the electron transport material mixed solution 43 was set to a range from 5 mg/mL to 50 mg/mL. By setting the added amount to this range, the film formability of the metal oxide nanoparticles 41 having electron transport properties can be improved, and the light-emission characteristics and element characteristics of the red light-emitting element 5R, the green light-emitting element 5G, and the blue light-emitting element 5B can be improved as described later.

Note that in the present embodiment, for example, PEDOT:PSS is used as the hole injection layer 24HI illustrated in (a) of FIG. 4, (b) of FIG. 4, and (c) of FIG. 4, and for example, TFB is used as the hole transport layer 24HT, but the disclosure is not limited thereto.

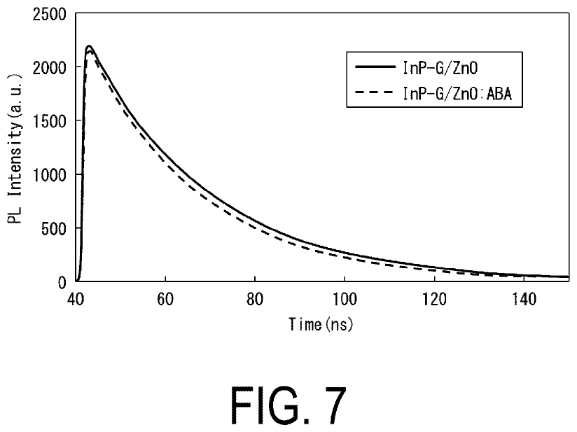

FIG. 7 is a graph showing a measurement result of a fluorescence lifetime of the green light-emitting element 5G provided in the display device 1 of the first embodiment and a measurement result of a fluorescence lifetime of a green light-emitting element of Comparative Example 1.

The green light-emitting element of Comparative Example 1 indicated by the solid line in FIG. 7 is provided with, in the following order, an anode serving as a first electrode 22, a hole injection layer 24HI, a hole transport layer 24HT, a light-emitting layer containing quantum dots (QDs) of a core structure constituted by InP with the core emitting green light, an electron transport layer configured from nanoparticles of zinc oxide (ZnO), and a cathode serving as a second electrode 25. The green light-emitting element 5G provided in the display device 1 of the first embodiment and indicated by the dashed line in FIG. 7 is provided with, in the following order, an anode serving as a first electrode 22, a hole injection layer 24HI, a hole transport layer 24HT, a light-emitting layer 24GEM containing quantum dots (QD) of a core structure constituted by InP with the core emitting green light, an electron transport layer 24ET formed from nanoparticles of zinc oxide (ZnO) and amino-benzoic acid added as the aromatic derivative 42, and a cathode serving as a second electrode 25. From the results of the fluorescence lifetime measurements presented in FIG. 7, it is clear that there is almost no difference between the fluorescence lifetime of the green light-emitting element 5G included in the display device 1 and provided with the electron transport layer 24ET containing zinc oxide (ZnO) nanoparticles and amino-benzoic acid (ABA) added as the aromatic derivative 42, and the fluorescence lifetime of the green light-emitting element of Comparative Example 1 provided with the electron transport layer formed of zinc oxide (ZnO) nanoparticles, and thus there is almost no difference between the rate of transport of electrons towards the light-emitting layer by the electron transport layer 24ET and the rate of transport of electrons towards the light-emitting layer by the electron transport layer formed from zinc oxide (ZnO) nanoparticles. From the above, it is clear that the chemical modification of the zinc oxide (ZnO) nanoparticles with amino-benzoic acid does not adversely affect the electron transport rate of the electron transport layer.

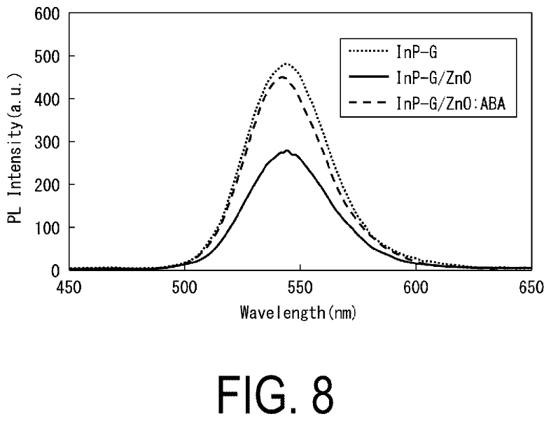

FIG. 8 is a graph presenting a measurement result of a PL intensity (photoluminescence emission intensity) of the green light-emitting element 5G provided in the display device 1 of the first embodiment, a measurement result of the PL intensity of the green light-emitting element of Comparative Example 1, and a measurement result of the PL intensity of a green light-emitting element of Comparative Example 2.

The green light-emitting element of Comparative Example 2 indicated by the dotted line in FIG. 8 is provided with, in the following order, an anode serving as a first electrode 22, a hole injection layer 24HI, a hole transport layer 24HT, a light-emitting layer containing quantum dots (QDs) of a core structure constituted by InP with the core emitting green light, and a cathode serving as a second electrode 25. The green light-emitting element of Comparative Example 1 indicated by the solid line in FIG. 8 and the green light-emitting element 5G provided in the display device 1 of the first embodiment and indicated by the dashed line in FIG. 8 are as described above. From the measurement results of the PL intensities presented in FIG. 8, it was confirmed that an electron trap of the nanoparticles of zinc oxide (ZnO) was successfully covered by chemically modifying the zinc oxide (ZnO) nanoparticles with amino-benzoic acid containing an amino group and a proton as electron-donating groups, and thus the PL intensity was significantly improved in comparison to the green light-emitting element of Comparative Example 1.

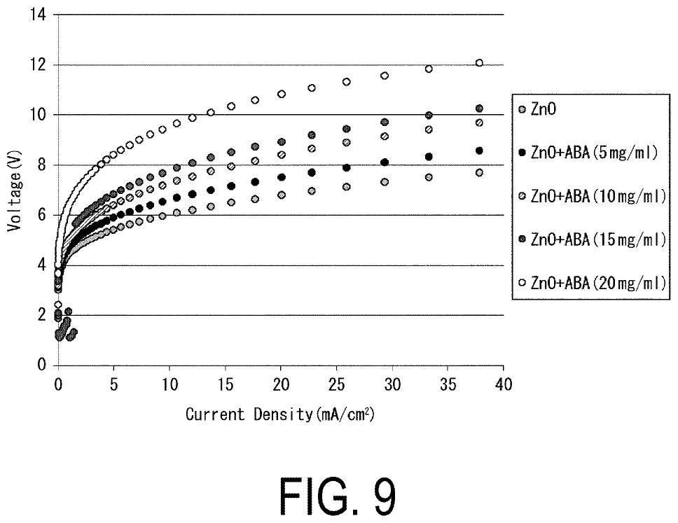

FIG. 9 is a graph showing the current densities and voltage characteristics of the green light-emitting element 5G provided in the display device 1 of the first embodiment, of first to third modified examples of the green light-emitting element 5G provided in the display device 1 of the first embodiment, and of the green light-emitting element of Comparative Example 1.

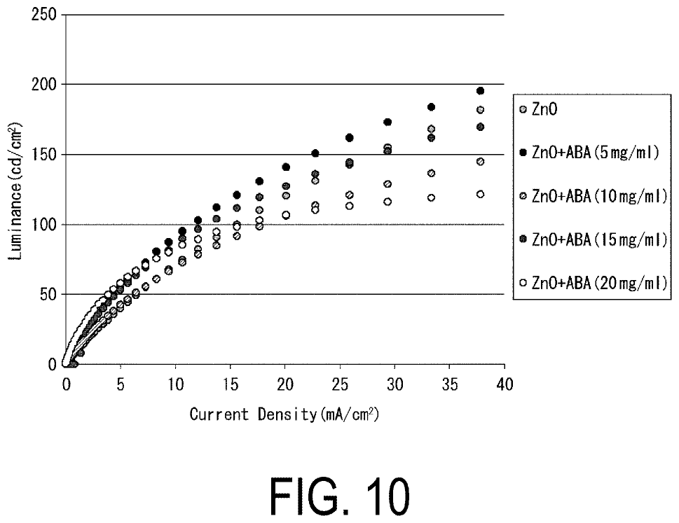

FIG. 10 is a graph showing the current densities and luminance characteristics of the green light-emitting element 5G provided in the display device 1 of the first embodiment, of the first to third modified examples of the green light-emitting element 5G provided in the display device 1 of the first embodiment, and of the green light-emitting element of Comparative Example 1.

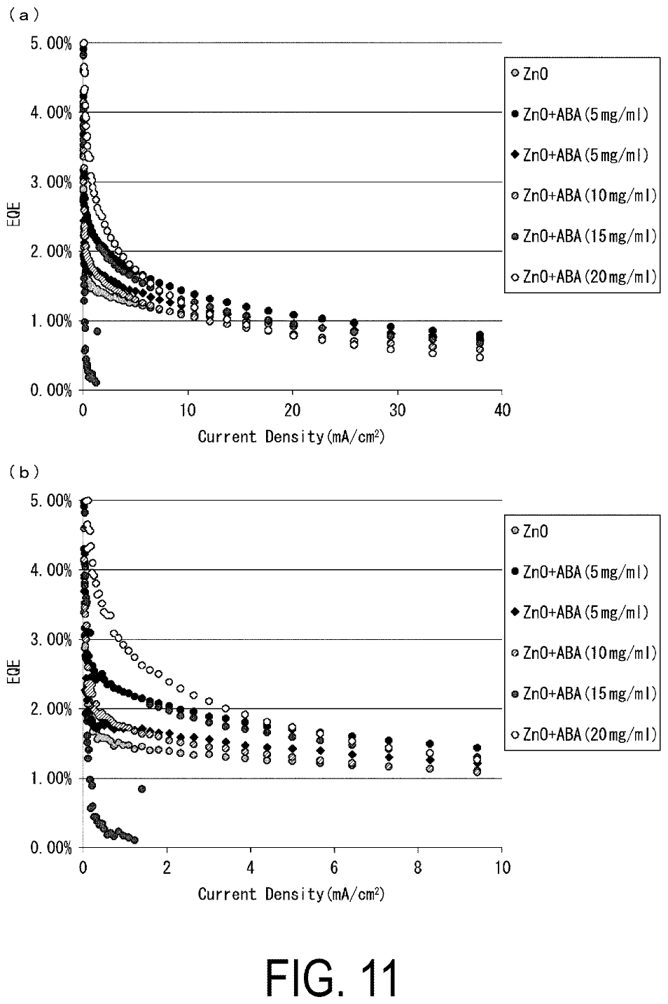

(a) of FIG. 11 is a graph showing the current densities and EQE characteristics of the green light-emitting element 5G provided in the display device 1 of the first embodiment, of the first to third modified examples of the green light-emitting element 5G included in the display device 1 of the first embodiment, and of the green light-emitting element of Comparative Example 1, and (b) of FIG. 11 is a partial enlarged view of a current density range of from 0 to 10 mA/cm² of the graph shown in (a) of FIG. 11 and showing the current densities and EQE characteristics.

The configurations of the first to third modified examples of the green light-emitting element 5G provided in the display device 1 according to the first embodiment are the same as the configuration of the green light-emitting element 5G provided in the display device 1 according to the first embodiment described above, with the exception that in the green light-emitting element 5G, the amount of amino-benzoic acid added to the electron transport material mixed solution 43 was set to 20 mg/mL, in the first modified example of the green light-emitting element 5G, the amount of amino-benzoic acid added to the electron transport material mixed solution 43 was set to 5 mg/mL, in the second modified example of the green light-emitting element 5G, the amount of amino-benzoic acid added to the electron transport material mixed solution 43 was set to 10 mg/mL, and in the third modified example of the green light-emitting element 5G, the amount of amino-benzoic acid added to the electron transport material mixed solution 43 was set to 15 mg/mL. The configuration of the green light-emitting element of Comparative Example 1 was as described above.

From the results of the current densities and voltage characteristics presented in FIG. 9 and the results of the current densities and luminance characteristics presented in FIG. 10, it can be confirmed that regardless of the added amount of amino-benzoic acid, the electroluminescent emission characteristics (EL characteristics) were not adversely affected by the addition of amino-benzoic acid in any of the green light-emitting element 5G and the first to third modified examples of the green light-emitting element 5G.

Furthermore, from the results of the current densities and EQE characteristics presented in (a) of FIG. 11 and (b) of FIG. 11, it can be confirmed that in a low current density area (for example, an area of 6 mA/cm² or less) to be usefully used, regardless of the added amount of amino-benzoic acid, the external quantum efficiency (EQE) was improved by the addition of amino-benzoic acid in each of the green light-emitting element 5G and the first to third modified examples of the green light-emitting element 5G as compared with the green light-emitting element of Comparative Example 1.

### Second Embodiment

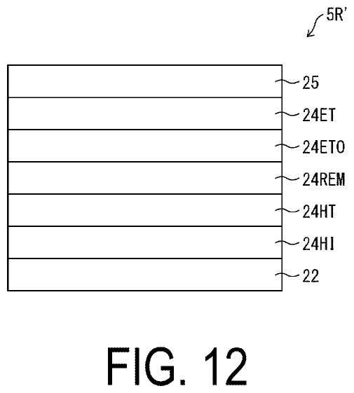

Next, with reference to FIG. 12, a second embodiment of the disclosure will be described. The present embodiment differs from the above-described first embodiment in that a non-polar underlayer (first layer) including at least a light-emitting layer is a layered film of any of a light-emitting layer 24REM (red light-emitting layer), a light-emitting layer 24GEM (green light-emitting layer), and a light-emitting layer 24BEM (blue light-emitting layer), and an electron transport layer 24ETO formed from an organic material. The other details are as described in the first embodiment. For convenience of description, members having the same functions as those illustrated in diagrams of the first embodiment are denoted by the same reference signs, and descriptions thereof are omitted.

FIG. 12 is a cross-sectional view illustrating a schematic configuration of a red light-emitting element 5R′ provided in a display device of a second embodiment.

In the red light-emitting element 5R′ illustrated in FIG. 12, the non-polar underlayer including at least the light-emitting layer 24REM and provided on an anode serving as a first electrode 22 is a layered film of the light-emitting layer 24REM (red light-emitting layer) and an electron transport layer 24ETO made of an organic material. Since the electron transport layer 24ETO made of an organic material is constituted by organic molecules, the surface of the electron transport layer 24ETO exhibits non-polarity (water repellency). Here, only the red light-emitting element 5R′ is illustrated, but in a green light-emitting element, a non-polar underlayer including at least the light-emitting layer 24GEM and provided on an anode serving as a first electrode 22 is a layered film of the light-emitting layer 24GEM (green light-emitting layer) and an electron transport layer 24ETO made of an organic material, and in the blue light-emitting element, a non-polar underlayer including at least the light-emitting layer 24BEM and provided on an anode serving as the first electrode 22 is a layered film of the light-emitting layer 24BEM (blue light-emitting layer) and an electron transport layer 24ETO made of an organic material.

The electron transport layer 24ETO can be formed using an electron transport material including at least one selected from the group consisting of, for example, 1,3,5-tris(1-phenyl-1H-benzimidazol-2-yl)benzene, 3-(biphenyl-4-yl)-5-(4-tert-butylphenyl)-4-phenyl-4H-1,2,4-triazole, bathophenanthroline, and tris(2,4,6-trimethyl-3-(pyridin-3-yl)phenyl) borane, for example.

As described above in the first embodiment, the surface of the metal oxide nanoparticle 41 having polarity and electron transport properties and contained in the electron transport layer 24ET (second layer) formed directly on the electron transport layer 24ETO serving as a non-polar underlayer illustrated in FIG. 12 is chemically modified with at least one aromatic derivative selected from among an aromatic derivative having a benzene ring skeleton containing one or more carboxyl groups and an aromatic derivative having a biphenyl skeleton containing one or more carboxyl groups, thereby improving the film formability of the metal oxide nanoparticle 41 having electron transport properties.

In addition, as described above in the first embodiment, through chemical modification using the aromatic derivative 42 including the electron-donating group, the metal oxide nanoparticles 41 having electron transport properties can be configured so as to have a dipolar property, and the light-emission characteristics and element characteristics of the red light-emitting element 5R′, the green light-emitting element, and the blue light-emitting element can be improved.

Note that the electron transport layer 24ET provided between the cathode serving as the second electrode 25 and the electron transport layer 24ETO made of an organic material is provided as an electron injection-cum-transport layer that also functions as an electron injection layer.

### Third Embodiment

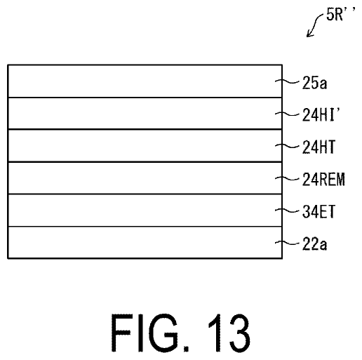

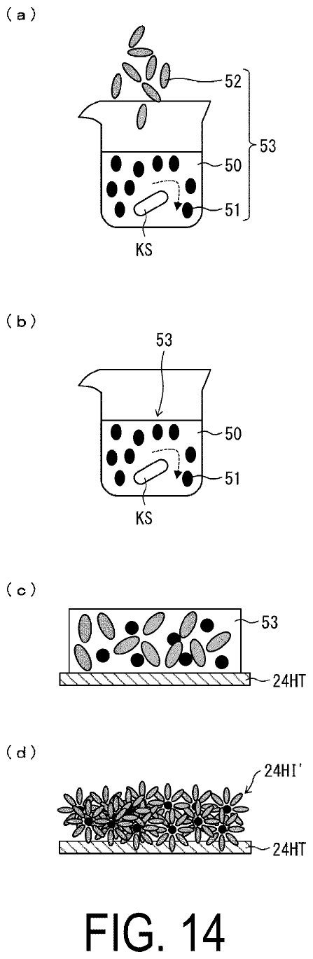

Next, a third embodiment of the disclosure will be described with reference to FIG. 13 and FIG. 14. The present embodiment differs from the above-described first and second embodiments in that a non-polar underlayer (first layer) including at least a light-emitting layer is a layered film of any of a light-emitting layer 24REM (red light-emitting layer), a light-emitting layer 24GEM (green light-emitting layer), and a light-emitting layer 24BEM (blue light-emitting layer), and a hole transport layer 24HT formed from an organic material, and the light-emitting element has an inversely layered structure. The other details are as described in the first and second embodiments. For convenience of description, members having the same functions as the members illustrated in the diagrams in the first and second embodiments are denoted by the same reference signs, and descriptions thereof will be omitted.

FIG. 13 is a cross-sectional view illustrating a schematic configuration of a red light-emitting element 5R″ provided in the display device of the third embodiment.

A red light-emitting element 5R″ illustrated in FIG. 13 has an inversely layered structure in which a cathode serving as a first electrode 22a, an electron transport layer 34ET, a light-emitting layer 24REM (red light-emitting layer), a hole transport layer 24HT, a hole injection layer 24HI′, and an anode service as a second electrode 25 are formed in this order from a substrate (not illustrated) side, and therefore the anode serving as the second electrode 25a is arranged as an upper layer further above the cathode serving as the first electrode 22a. Thus, in order to realize a top-emitting type light-emitting element, the cathode serving as the first electrode 22a may be formed from an electrode material that reflects visible light, and the anode serving as the second electrode 25a may be formed from an electrode material that transmits visible light, and in order to realize a bottom-emitting type light-emitting element, the cathode serving as the first electrode 22a may be formed from an electrode material that transmits visible light, and the anode serving as the second electrode 25a may be formed from an electrode material that reflects visible light. In the red light-emitting element 5R″, the non-polar underlayer including at least the light-emitting layer 24REM and provided on the cathode serving as the first electrode 22a is a layered film of the light-emitting layer 24REM (red light-emitting layer) and a hole transport layer 24HT made of an organic material. Here, only the red light-emitting element 5R″ is illustrated, but in a green light-emitting element, a non-polar underlayer including at least the light-emitting layer 24GEM and provided on a cathode serving as a first electrode 22a is a layered film of the light-emitting layer 24GEM (green light-emitting layer) and a hole transport layer 24HT made of an organic material, and in the blue light-emitting element, a non-polar underlayer including at least the light-emitting layer 24BEM and provided on a cathode serving as the first electrode 22a is a layered film of the light-emitting layer 24BEM (blue light-emitting layer) and a hole transport layer 24HT made of an organic material. Note that in the present embodiment, an electron transport layer constituted by metal oxide nanoparticles or the like having electron transport properties is used as the electron transport layer 34ET, but when the light-emitting layer is formed by a vapor deposition method, the electron transport layer is not limited thereto, and an organic material or the like having electron transport properties may be used.

In the present embodiment, in order to improve the film formability of the hole injection layer 24HI′ (second layer), that is, the metal oxide nanoparticles having hole injection properties and hole transport properties, the hole injection layer 24HI′ including metal oxide nanoparticles having hole injection properties and hole transport properties and formed directly on the hole transport layer 24HT formed from an organic material and serving as a non-polar underlayer, at least one aromatic derivative selected from an aromatic derivative having a benzene ring skeleton containing one or more carboxyl groups and an aromatic derivative having a biphenyl skeleton containing one or more carboxyl groups is added to the hole injection layer 24HI′.

(a) of FIG. 14, (b) of FIG. 14, (c) of FIG. 14, and (d) of FIG. 14 are diagrams illustrating steps for forming the hole injection layer 24HI′ provided in the display device of the third embodiment.

In the present embodiment, as illustrated in (a) of FIG. 14, the above-described aromatic derivative 52 is added while stirring, with a stirrer KS for example, a metal oxide nanoparticle dispersion obtained by dispersing metal oxide nanoparticles 51 having at least hole transport properties (having hole injection properties and hole transport properties) in a polar solvent 50, and further stirring with, for example, the stirrer KS to thereby manufacture, as illustrated in (b) of FIG. 14, a hole transport material mixed solution 53 containing the polar solvent 50, the metal oxide nanoparticles 51 having at least hole transport properties, and the above-described aromatic derivative 52. The hole transport material mixed solution 53 is not limited thereto, and may be manufactured by simultaneously inserting the metal oxide nanoparticles 51 having at least hole transport properties and the above-described aromatic derivative 52 into the polar solvent 50 and stirring the mixture using, for example, the stirrer KS.

Subsequently, as illustrated in (c) of FIG. 14, the hole transport material mixed solution 53 can be formed directly on the hole transport layer 24HT, which is a non-polar underlayer, using, for example, a spin coating method, an ink-jet method, a bar coating method, a blade coating method, a roll coating method, a dipping method, a gravure coating method, a flexographic printing method, or a spray coating method. By using, among these methods, the ink-jet method, the hole transport material mixed solution 53 can be formed only inside a frame-shaped bank 23 illustrated in (a) of FIG. 4, (b) of FIG. 4, and (c) of FIG. 4, and the hole injection layer 24HI′ can be selectively formed only in necessary locations without increasing the number of manufacturing steps.

Subsequently, as illustrated in (c) of FIG. 14, the hole transport material mixed solution 53 formed directly on the hole transport layer 24HT, which is a non-polar underlayer, is subjected, as necessary, to a heat treatment (for example, at 80° C. for a predetermined amount of time) to remove the polar solvent 50, whereby the hole injection layer 24HI′ can be formed directly on the hole transport layer 24HT, which is a non-polar underlayer, as illustrated in (d) of FIG. 14. The heat treatment temperature and the heat treatment time can be appropriately set according to the type of the polar solvent 50 to be used. The heat treatment is preferably implemented to further improve productivity, but the disclosure is not limited thereto, and for example, the hole transport material mixed solution 53 formed on the hole transport layer 24HT may be left standing at room temperature without being subjected to the heat treatment.

The surfaces of the metal oxide nanoparticles 51 having polarity and at least hole transport properties and contained in the hole injection layer 24HI′ illustrated in (d) of FIG. 14 are chemically modified with at least one aromatic derivative selected from an aromatic derivative having a benzene ring skeleton containing one or more carboxyl groups and an aromatic derivative having a biphenyl skeleton containing one or more carboxyl groups. Specifically, when the carboxyl group of the above-described aromatic derivative 52 is disposed on the surface of the metal oxide nanoparticle 51 having polarity and at least hole transport properties, the aromatic derivative having a benzene ring skeleton and/or the aromatic derivative having a biphenyl skeleton covers the surface of the metal oxide nanoparticle 51 having polarity and at least hole transport properties, and therefore the surface of the metal oxide nanoparticle 51 having at least the hole transport properties is made non-polar (water repellent). Accordingly, the film formability of the metal oxide nanoparticles 51 having at least hole transport properties and formed directly on the hole transport layer 24HT, which is a non-polar underlayer, can be improved.

As the metal oxide nanoparticles 51 having at least hole transport properties, nanoparticles of a metal oxide containing at least one selected from Ni, Mg, Mo, Cu, Co, Cr, and Ti are preferably used, and nanoparticles of nickel oxide (NiO) are more preferably used. Note that the particle size of the metal oxide nanoparticle 51 is preferably from 2 nm to 30 nm. Setting the particle size of the metal oxide nanoparticle 51 to equal to or greater than 2 nm facilitates control of the particle size of the metal oxide nanoparticle 51. Furthermore, when the particle size of the metal oxide nanoparticle 51 is set to equal to or less than 30 nm, the efficiency of injection of holes from the anode serving as the second electrode 25a into the hole injection layer 24HI′ can be improved.

As the polar solvent 50, it is preferable to use an alcohol-based solvent in consideration of the dispersibility of the metal oxide nanoparticles 51 exhibiting polarity and hole transport properties, and for example, ethanol, propanol, butanol, or the like can be suitably used.

From the viewpoint of improving the film formability of the metal oxide nanoparticles 51 having at least hole transport properties, as the above-described aromatic derivative 52, at least one aromatic derivative selected from the aromatic derivative having a benzene ring skeleton containing one or more carboxyl groups and the aromatic derivative having a biphenyl skeleton containing one or more carboxyl groups, the aromatic derivatives thereof being described above in the first embodiment and being based on Chemical Formula 1 to Chemical Formula 7, may be used.

As in the present embodiment, when the surfaces of the metal oxide nanoparticles 51 having polarity and at least hole transport properties and contained in the hole injection layer 24HI′ are modified, one or more of R1 to R5 in the following Chemical Formula 1 are preferably an electron-withdrawing group.

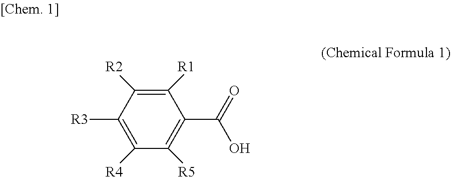

The electron-withdrawing group is preferably any of a nitro group, a cyano group, a chloro group, a bromo group, a fluoro group, and a trifluoromethyl group. Through chemical modification using the aromatic derivative 52 including the electron-withdrawing group in this manner, the metal oxide nanoparticles 51 having at least hole transport properties can be configured so as to have a dipolar property, and the light-emission characteristics and element characteristics of the red light-emitting element 5R″, the green light-emitting element, and the blue light-emitting element can be improved.

The following Chemical Formula 8 is a nitro-benzoic acid (for example, 4-nitro-benzoic acid) and is an example of an aromatic derivative having a benzene ring skeleton containing one or more carboxyl groups. In the compound of Chemical Formula 8, R3 of Chemical Formula 1 described above is nitro group, which is an electron-withdrawing group, and R1, R2, R4, and R5 of Chemical Formula 1 are each a proton.

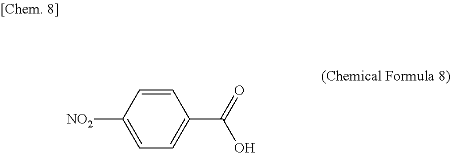 [SMILES: O=C(O)c1ccc([N+](=O)[O-])cc1]

The following Chemical Formula 9 is a cyano-benzoic acid (for example, 4-cyano-benzoic acid) and is an example of an aromatic derivative having a benzene ring skeleton containing one or more carboxyl groups. In the compound of Chemical Formula 9, R3 of Chemical Formula 1 described above is a cyano group, which is an electron-withdrawing group, and R1, R2, R4, and R5 of Chemical Formula 1 are each a proton.

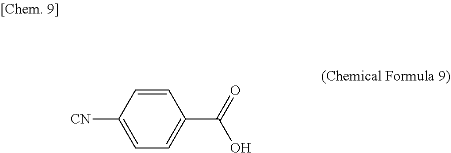

Although not illustrated, the aromatic derivative of the benzene ring skeleton having one or more carboxyl groups may be a chloro-benzoic acid (for example, p-chloro-benzoic acid) containing an electron-withdrawing chloro group, a bromo-benzoic acid (for example, p-bromo-benzoic acid) containing an electron-withdrawing bromo group, a fluoro-benzoic acid (for example, 4-fluoro-benzoic acid) containing an electron-withdrawing fluoro group, or a trifluoromethyl benzoic acid (for example, 4-(trifluoromethyl) benzoic acid) containing an electron-withdrawing trifluoromethyl group.

Also, in the case in which the surfaces of the metal oxide nanoparticles 51 having polarity and at least hole transport properties and contained in the hole injection layer 24HI′ are modified as in the present embodiment, preferably at least one of R11 to R20 in the following Chemical Formula 4 is a carboxyl group, and the remaining of R11 to R20 in Chemical Formula 4 other than the carboxyl group are one or more electron-withdrawing groups.

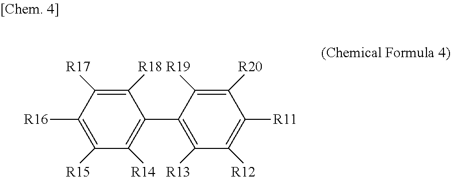

The following Chemical Formula 10 is a bromo-biphenylcarboxylic acid (for example, 4′-bromo-3-biphenyl carboxylic acid), and is an example of an aromatic derivative having a biphenyl skeleton containing one or more carboxyl groups. In the compound of Chemical Formula 10, R20 of Chemical Formula 4 above is a carboxyl group, R16 of Chemical Formula 4 is an electron-withdrawing bromo group, and R11 to R15 and R17 to R19 of Chemical Formula 1 are protons.

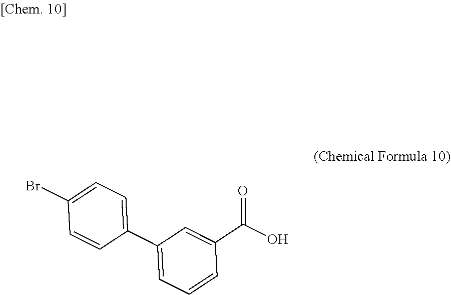 [SMILES: O=C(O)c1cccc(-c2ccc(Br)cc2)c1]

Although not illustrated, the aromatic derivative of the biphenyl skeleton having one or more carboxyl groups may be a nitro-biphenylcarboxylic acid (for example, 2′-nitro-4-biphenylcarboxylic acid) containing an electron-withdrawing nitro group, may be a cyano-biphenylcarboxylic acid (for example, 2′-cyanobiphenyl-2-carboxylic acid) containing an electron-withdrawing cyano group, may be a chloro-biphenylcarboxylic acid (for example, 4′-chlorobiphenyl-3-carboxylic acid) containing an electron-withdrawing chloro group, may be a fluoro-biphenylcarboxylic acid (for example, 4′-fluoro-4-biphenylcarboxylic acid) containing an electron-withdrawing fluoro group, or may be a trifluoromethyl biphenylcarboxylic acid (for example, 4′-(trifluoromethyl)-2-biphenylcarboxylic acid) containing an electron-withdrawing trifluoromethyl group.

Further, as the aromatic derivative 52 described above, both the above-described aromatic derivative having a benzene ring skeleton containing one or more carboxyl groups and one or more electron-withdrawing groups and the above-described aromatic derivative having a biphenyl skeleton containing one or more carboxyl groups and one or more electron-withdrawing groups may be mixed and used.

In the present embodiment, an example was described in which ethanol was used as the polar solvent 50, nanoparticles of nickel oxide (NiO) were used as the metal oxide nanoparticles 51 having at least hole transport properties, and a nitro-benzoic acid represented by Chemical Formula 8 above was used as the aromatic derivative 52 described above. However, the disclosure is not limited thereto. Furthermore, the amount of nitro-benzoic acid added to the hole transport material mixed solution 53 was set to a range from 5 mg/mL to 50 mg/mL. By setting the added amount to this range, the film formability of the metal oxide nanoparticles 51 having at least hole transport properties can be improved, and the light-emission characteristics and element characteristics of the red light-emitting element 5R″, the green light-emitting element, and the blue light-emitting element can be improved.

Note that the hole injection layer 24HI′ provided between the anode serving as the second electrode 25a and the hole transport layer 24HT formed from an organic material is provided as a hole injection-cum-transport layer that also functions as a hole transport layer.

### Fourth Embodiment

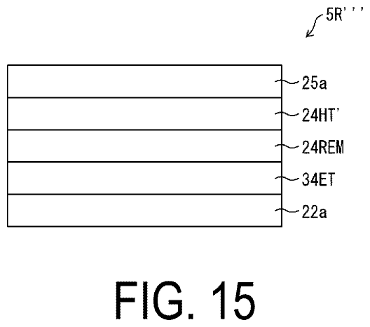

Next, a description is given of a fourth embodiment of the disclosure on the basis of FIG. 15. The present embodiment differs from the above-described third embodiment in that a non-polar underlayer (first layer) including at least a light-emitting layer is any of a light-emitting layer 24REM (red light-emitting layer), a light-emitting layer 24GEM (green light-emitting layer), and a light-emitting layer 24BEM (blue light-emitting layer). The other details are as described in the third embodiment. For convenience of explanation, members having the same functions as those of the members illustrated in the drawings in the third embodiment are denoted by the same reference numerals, and descriptions thereof will be omitted.

FIG. 15 is a cross-sectional view illustrating a schematic configuration of a red light-emitting element 5R′″ provided in the display device of the fourth embodiment.

The red light-emitting element 5R′″ illustrated in FIG. 15 has an inversely layered structure in which a cathode serving as the first electrode 22a, an electron transport layer 34ET, a light-emitting layer 24REM (red light-emitting layer), a hole transport layer 24HT′, and an anode serving as a second electrode 25 are formed in this order from a substrate (not illustrated) side. In the red light-emitting element 5R″, the non-polar underlayer including at least the light-emitting layer 24REM and provided on the cathode serving as the first electrode 22a is the light-emitting layer 24REM (red light-emitting layer). Here, only the red light-emitting element 5R′″ is illustrated, but in a green light-emitting element, a non-polar underlayer including at least the light-emitting layer 24GEM and provided on a cathode serving as a first electrode 22a is the light-emitting layer 24GEM (green light-emitting layer), and in the blue light-emitting element, a non-polar underlayer including at least the light-emitting layer 24BEM and provided on a cathode serving as the first electrode 22a is the light-emitting layer 24BEM (blue light-emitting layer).

In the present embodiment, at least one aromatic derivative selected from among an aromatic derivative having a benzene ring skeleton containing one or more carboxyl groups and an aromatic derivative having a biphenyl skeleton containing one or more carboxyl groups is added to the hole transport layer 24HT′ in order to improve the film formability of the hole transport layer 24HT′ (second layer), that is, the metal oxide nanoparticles having the hole transport properties, with the hole transport layer 24HT′ (second layer) including metal oxide nanoparticles having hole transport properties and formed directly on the light-emitting layer 24REM (red light-emitting layer), the light-emitting layer 24GEM (green light-emitting layer), and the light-emitting layer 24BEM (blue light-emitting layer), which are non-polar underlayers.

In the present embodiment, an example was described in which dimethyl sulfoxide (DMSO) was used as the polar solvent, nanoparticles of nickel oxide (NiO) were used as the metal oxide nanoparticles having hole transport properties, and a nitro-benzoic acid represented by Chemical Formula 8 above was used as the aromatic derivative described above. However, the disclosure is not limited thereto. Furthermore, the amount of nitro-benzoic acid added to the hole transport material mixed solution was set to a range from 5 mg/mL to 50 mg/mL. By setting the added amount to this range, the film formability of the metal oxide nanoparticles having hole transport properties can be improved, and the light-emission characteristics and element characteristics of the red light-emitting element 5R′″, the green light-emitting element, and the blue light-emitting element can be improved.

Note that the step of forming, directly on the light-emitting layer 24REM (red light-emitting layer), the light-emitting layer 24GEM (green light-emitting layer), and the light-emitting layer 24BEM (blue light-emitting layer), which are non-polar underlayers, the hole transport layer 24HT′ containing the metal oxide nanoparticles having hole transport properties is the same as the step of forming the hole injection layer 24HI′ directly on the hole transport layer 24HT, which is a non-polar underlayer described on the basis of FIG. 14 in the third embodiment, and thus the formation step thereof will not be described here.

### SUPPLEMENT

### First Aspect

A light-emitting element including:

a first electrode;

a first layer provided on the first electrode and including at least a light-emitting layer, the first layer being non-polar;

a second layer provided directly on the first layer and including at least one aromatic derivative selected from an aromatic derivative having a benzene ring skeleton containing one or more carboxyl groups and an aromatic derivative having a biphenyl skeleton containing one or more carboxyl groups, and metal oxide nanoparticles having electron transport properties or hole transport properties; and

a second electrode provided on the second layer.

### Second Aspect

The light-emitting element according to the first aspect,

wherein the metal oxide nanoparticles have electron transport properties,

the first electrode is an anode,

the second electrode is a cathode, and

the second layer is an electron transport layer or an electron injection-cum-transport layer.

### Third Aspect

The light-emitting element according to the second aspect,

wherein the metal oxide nanoparticles are nanoparticles of a metal oxide comprising at least one selected from Zn, Mg, Ti, Si, Sn, W, Ta, Ba, Zr, Al, Y, and Hf.

### Fourth Aspect

The light-emitting element according to the third aspect,

wherein the metal oxide nanoparticles are nanoparticles of zinc oxide or magnesium zinc oxide.

### Fifth Aspect

The light-emitting element according to any of the second to fourth aspects,

wherein the aromatic derivative further includes an electron-donating group.

### Sixth Aspect

The light-emitting element according to the fifth aspect,

wherein the electron-donating group is any of an amino group, a methoxy group, an ethoxy group, and a proton.

### Seventh Aspect

The light-emitting element according to any of the second to sixth aspects,

wherein the aromatic derivative having a benzene ring skeleton containing one or more carboxyl groups is any of benzoic acid, amino-benzoic acid, methoxybenzoic acid, and ethoxybenzoic acid.

### Eighth Aspect

The light-emitting element according to any of the second to seventh aspects,

wherein the aromatic derivative having a biphenyl skeleton containing one or more carboxyl groups is any of biphenylcarboxylic acid, amino biphenylcarboxylic acid, methoxy biphenylcarboxylic acid, and ethoxy biphenylcarboxylic acid.

### Ninth Aspect

The light-emitting element according to the first aspect,

wherein the metal oxide nanoparticles have hole transport properties,

the first electrode is a cathode,

the second electrode is an anode, and

the second layer is a hole transport layer or a hole injection-cum-transport layer.

### Tenth Aspect

The light-emitting element according to the ninth aspect,

wherein the metal oxide nanoparticles are nanoparticles of a metal oxide comprising at least one selected from Ni, Mg, Mo, Cu, Co, Cr, and Ti.

### Eleventh Aspect

The light-emitting element according to the tenth aspect,

wherein the metal oxide nanoparticles are nanoparticles of nickel oxide.

### Twelfth Aspect

The light-emitting element according to any of the ninth to eleventh aspects,

wherein the aromatic derivative further includes an electron-withdrawing group.

### Thirteenth Aspect

The light-emitting element according to the twelfth aspect,

wherein the electron-withdrawing group is any of a nitro group, a cyano group, a chloro group, a bromo group, a fluoro group, and a trifluoromethyl group.

### Fourteenth Aspect

The light-emitting element according to any of the ninth to thirteenth aspects,

wherein the aromatic derivative having a benzene ring skeleton containing one or more carboxyl groups is any of nitro-benzoic acid, cyano-benzoic acid, chloro-benzoic acid, bromo-benzoic acid, fluoro-benzoic acid, and trifluoromethyl benzoic acid.

### Fifteenth Aspect

The light-emitting element according to any of the ninth to fourteenth aspects,

wherein the aromatic derivative having a biphenyl skeleton containing one or more carboxyl groups is any of nitro-biphenylcarboxylic acid, cyano-biphenylcarboxylic acid, chloro-biphenylcarboxylic acid, bromo-biphenylcarboxylic acid, fluoro-biphenylcarboxylic acid, and trifluoromethyl biphenylcarboxylic acid.

### Sixteenth Aspect

The light-emitting element according to any of the first to fifteenth aspects,

wherein the first layer is a light-emitting layer including quantum dots and organic ligands.

### Seventeenth Aspect

The light-emitting element according to any of the first to fifteenth aspects,

wherein the first layer is an organic light-emitting layer.

### Eighteenth Aspect

The light-emitting element according to any of the second to eighth aspects,

wherein the second layer is an electron injection-cum-transport layer, and

the first layer is a layer in which a light-emitting layer or an organic light-emitting layer, and an electron transport layer formed from an organic material are layered in this order from a side of the first electrode side, the light-emitting layer including quantum dots and organic ligands.

### Nineteenth Aspect

The light-emitting element according to any of the ninth to fifteenth aspects,

wherein the second layer is a hole injection-cum-transport layer, and

the first layer is a layer in which a light-emitting layer or an organic light-emitting layer, and a hole transport layer formed from an organic material are layered in this order from a side of the first electrode side, the light-emitting layer including quantum dots and organic ligands.

### Twentieth Aspect

A display device provided with a plurality of the light-emitting elements described in any of the first to nineteenth aspects, the plurality of the light-emitting elements being provided on a substrate and including a first light-emitting element, a second light-emitting element, and a third light-emitting element,

wherein the first light-emitting element is provided with, as the light-emitting layer, a first light-emitting layer,

the second light-emitting element is provided with, as the light-emitting layer, a second light-emitting layer having a light-emission peak wavelength differing from a light-emission peak wavelength of the first light-emitting layer, and

the third light-emitting element is provided with, as the light-emitting layer, a third light-emitting layer having a light-emission peak wavelength differing from the light-emission peak wavelengths of the first light-emitting layer and the second light-emitting layer.

### Twenty-First Aspect

A method of manufacturing a light-emitting element, the method including:

forming a first electrode;

forming, on the first electrode, a first layer including at least a light-emitting layer, the first layer being non-polar;

forming a second layer by forming a mixed solution directly on the first layer, the mixed solution including at least one aromatic derivative selected from an aromatic derivative having a benzene ring skeleton containing one or more carboxyl groups and an aromatic derivative having a biphenyl skeleton containing one or more carboxyl groups, metal oxide nanoparticles having electron transport properties or hole transport properties, and a polar solvent; and

forming a second electrode on the second layer.

### Twenty-Second Aspect

The method of manufacturing a light-emitting element according to the twenty-first aspect,

wherein the mixed solution is manufactured by adding the aromatic derivative while stirring a metal oxide nanoparticle dispersion having the metal oxide nanoparticles dispersed in the polar solvent.

### Twenty-Third Aspect

The method of manufacturing a light-emitting element according to the twenty-first or twenty-second aspect,

wherein in the forming of the second layer, the second layer is formed by heat treatment after having formed the mixed solution directly on the first layer.

### Twenty-Fourth Aspect

The method of manufacturing a light-emitting element according to any of the twenty-first to twenty-third aspects,

wherein an alcohol-based solvent or dimethyl sulfoxide is used as the polar solvent.

### Twenty-Fifth Aspect

The method of manufacturing a light-emitting element according to any of the twenty-first to twenty-fourth aspects,

wherein an added amount of the aromatic derivative in the mixed solution is from 5 mg/mL to 50 mg/mL.

### Twenty-Sixth Aspect

The method of manufacturing a light-emitting element according to any of the twenty-first to twenty-fifth aspects,

wherein in the forming of the second layer, the mixed solution is formed directly on the first layer by an ink-jet method.

### Twenty-Seventh Aspect

The method of manufacturing a light-emitting element according to any of the twenty-first to twenty-sixth aspects,

wherein the metal oxide nanoparticles have electron transport properties, and the second layer is an electron transport layer.

### Twenty-Eighth Aspect

The method of manufacturing a light-emitting element according to any of the twenty-first to twenty-sixth aspects,

wherein the metal oxide nanoparticles have hole transport properties, and the second layer is a hole transport layer.

### Twenty-Ninth Aspect

A method of manufacturing a display device, the method including:

forming a light-emitting element on a substrate by the method of manufacturing a light-emitting element described in any of the twenty-first to the twenty-eighth aspects.

### APPENDIX

The disclosure is not limited to each of the embodiments described above, and various modifications may be made within the scope of the claims. Embodiments obtained by appropriately combining technical approaches disclosed in each of the different embodiments also fall within the technical scope of the disclosure. Furthermore, novel technical features can be formed by combining the technical approaches disclosed in each of the embodiments.

### INDUSTRIAL APPLICABILITY

The disclosure can be applied to a light-emitting element, a method of manufacturing the light-emitting element, a display device, and a method of manufacturing the display device.

1. A light-emitting element comprising:
a first electrode;
a first layer provided on the first electrode and comprising at least a light-emitting layer, the first layer being non-polar;
a second layer provided directly on the first layer and comprising at least one aromatic derivative selected from an aromatic derivative having a benzene ring skeleton containing one or more carboxyl groups and an aromatic derivative having a biphenyl skeleton containing one or more carboxyl groups, and metal oxide nanoparticles having electron transport properties or hole transport properties; and
a second electrode provided on the second layer.

2. The light-emitting element according to claim 1,
wherein the metal oxide nanoparticles have electron transport properties,
the first electrode is an anode,
the second electrode is a cathode, and
the second layer is an electron transport layer or an electron injection-cum-transport layer.

3. The light-emitting element according to claim 2,
wherein the metal oxide nanoparticles are nanoparticles of a metal oxide comprising at least one selected from Zn, Mg, Ti, Si, Sn, W, Ta, Ba, Zr, Al, Y, and Hf.

4. The light-emitting element according to claim 3,
wherein the metal oxide nanoparticles are nanoparticles of zinc oxide or magnesium zinc oxide.

5. The light-emitting element according to claim 2,
wherein the aromatic derivative further comprises an electron-donating group.

6. The light-emitting element according to claim 5,
wherein the electron-donating group is any of an amino group, a methoxy group, an ethoxy group, and a proton.

7. The light-emitting element according to claim 2,
wherein the aromatic derivative having a benzene ring skeleton containing one or more carboxyl groups is any of benzoic acid, amino-benzoic acid, methoxybenzoic acid, and ethoxybenzoic acid.

8. The light-emitting element according to claim 2,
wherein the aromatic derivative having a biphenyl skeleton containing one or more carboxyl groups is any of biphenylcarboxylic acid, amino biphenylcarboxylic acid, methoxy biphenylcarboxylic acid, and ethoxy biphenylcarboxylic acid.

9. The light-emitting element according to claim 1,
wherein the metal oxide nanoparticles have hole transport properties,
the first electrode is a cathode,
the second electrode is an anode, and
the second layer is a hole transport layer or a hole injection-cum-transport layer.

10. The light-emitting element according to claim 9,
wherein the metal oxide nanoparticles are nanoparticles of a metal oxide comprising at least one selected from Ni, Mg, Mo, Cu, Co, Cr, and Ti.

11. The light-emitting element according to claim 10,
wherein the metal oxide nanoparticles are nanoparticles of nickel oxide.

12. The light-emitting element according to claim 9,
wherein the aromatic derivative further comprises an electron-withdrawing group.

13. The light-emitting element according to claim 12,
wherein the electron-withdrawing group is any of a nitro group, a cyano group, a chloro group, a bromo group, a fluoro group, and a trifluoromethyl group.

14. The light-emitting element according to claim 9,
wherein the aromatic derivative having a benzene ring skeleton containing one or more carboxyl groups is any of nitro-benzoic acid, cyano-benzoic acid, chloro-benzoic acid, bromo-benzoic acid, fluoro-benzoic acid, and trifluoromethyl benzoic acid.

15. The light-emitting element according to claim 9,
wherein the aromatic derivative having a biphenyl skeleton containing one or more carboxyl groups is any of nitro-biphenylcarboxylic acid, cyano-biphenylcarboxylic acid, chloro-biphenylcarboxylic acid, bromo-biphenylcarboxylic acid, fluoro-biphenylcarboxylic acid, and trifluoromethyl biphenylcarboxylic acid.

16. The light-emitting element according to claim 1,
wherein the first layer is a light-emitting layer comprising quantum dots and organic ligands.

17. The light-emitting element according to claim 1,
wherein the first layer is an organic light-emitting layer.

18. The light-emitting element according to claim 2,
wherein the second layer is an electron injection-cum-transport layer, and
the first layer is a layer in which a light-emitting layer or an organic light-emitting layer, and an electron transport layer comprising an organic material are layered in this order from a side of the first electrode, the light-emitting layer comprising quantum dots and organic ligands.

19. The light-emitting element according to claim 9,
wherein the second layer is a hole injection-cum-transport layer, and
the first layer is a layer in which a light-emitting layer or an organic light-emitting layer, and a hole transport layer comprising an organic material are layered in this order from a side of the first electrode, the light-emitting layer comprising quantum dots and organic ligands.

20. A display device, comprising:
a plurality of the light-emitting elements described in claim 1,
the plurality of the light-emitting elements being provided on a substrate and comprising a first light-emitting element, a second light-emitting element, and a third light-emitting element,
wherein the first light-emitting element comprises, as the light-emitting layer, a first light-emitting layer,
the second light-emitting element comprises, as the light-emitting layer, a second light-emitting layer having a light-emission peak wavelength differing from a light-emission peak wavelength of the first light-emitting layer, and
the third light-emitting element comprises, as the light-emitting layer, a third light-emitting layer having a light-emission peak wavelength differing from the light-emission peak wavelengths of the first light-emitting layer and the second light-emitting layer.

21-29. (canceled)
